(19) United States
(12) Patent Application Publication
(10) Pub. No.: US 2001/0042329 A1
(43) Pub. Date: Nov. 22, 2001

(54) Electroluminescent sign

(76) Inventors: Matthew Murasko, Manhattan Beach, CA (US); Clarence H. Duttlinger JR., St. Charles, MO (US)

Correspondence Address: LATHROP & GAGE, LC, Suite 2800, 2345 Grand Boulevard, Kansas City, MO, 64108, US

(21) Appl. No.: 09/814,673

(22) Filed: Mar. 22, 2001

Related U.S. Application Data
(63) Continuation-in-part of application No. 09/548,560, filed on Apr. 13, 2000.

(51) Int. Cl. G09F 13/22; H05K 1/00

(52) U.S. Cl. 40/544; 439/62; 439/59

(57) ABSTRACT

Signs including electroluminescent lamps are described. In accordance with one embodiment of the present invention the electroluminescent system has an electroluminescent lamp releasably and fixedly mateable with a slide connector to provide electrical energy for the light system.. The electroluminescent lamp includes a substrate, a rear electrode, a dielectric layer, a phosphor layer, a conductive layer, and a front electrode. The lamp further includes a tab interconnect tab portion, which receives the leads from the rear electrode and front electrode, and is configured to be releasably and fixedly mated with the connector.

### RELATED APPLICATIONS

The following application is a continuation-in-part of Patent Application Ser. No. 09/548,560, which is a continuation-in-part of Patent 6,203,391.

### FIELD OF INVENTION

This invention relates generally to electroluminescent lamps and, more particularly, to a connector for such lamps.

### BACKGROUND OF THE INVENTION

Electroluminescent (EL) lighting has been known in the art for many years as a source of light weight and relatively low power illumination. Because of these attributes, EL lamps are in common use today providing light in, for example, automobiles, airplanes, watches, and laptop computers. Electroluminescent lamps of the current art generally include a layer of phosphor positioned between two electrodes, with at least one of the electrodes being light-transmissive, and a dielectric layer positioned between the electrodes. The dielectric layer enables the lamp's capacitive properties. When a voltage is applied across the electrodes, the phosphor material is activated and emits a light.

It is standard in the art for the translucent electrode to consist of a polyester film sputtered with indium-tin-oxide, which provides a serviceable translucent material with suitable conductive properties for use as an electrode. Screen-printed ink systems have been developed that deposit layers of ink onto a substrate to provide electroluminescent lamps. For these systems, it is known for the light-transmissive or translucent electrode to consist of a suitable translucent electrical conductor, such as indium-tin-oxide, which is dispersed in a resin. This conductive layer of the electroluminescent lamp is in electrical contact with an electrode lead or bus bars. After the back electrode has been applied and a dielectric coating has been applied to separate the conductive layer from the rear electrode, a power lead is applied by crimping or pressing a portion through the layers of the electroluminescent lamps and against the conductive layer and a second power lead is attached to the rear electrode using the same application technique, either at a marginal location or at a convenient location inwardly of the panel margins.

A problem resides in this conventional placement of the electric power leads to the conductive layer and rear electrode of the electroluminescent lamp. Specifically, the crimping of the power leads to the respective bus bars or conductive layers can cause electrical failure or arcing as the electric current transfers through or around the crimp hole.

Further, the crimp holes may likewise cause breakdown of the capacitive structure of electroluminescent lamp due to silver from either the light-transmissive electrode lead or the opaque electrode migrating through the crimp holes to the other electrode. This short circuits the electroluminescent lamp and results in electroluminescent lamp failure.

A need therefore exists for power lead connections to the electroluminescent lamps that do not provide pathways for the electrical current or silver migration. A further need exists for a connector for an electroluminescent lamp system that may be easily, releasably and quickly coupled to electroluminescent lamp.

### BRIEF SUMMARY OF THE INVENTION

The present invention addresses the above-described problems of electroluminescent lamps standard in the art by providing an electroluminescent system having an electroluminescent lamp releasably and fixedly mateable with a slide connector to provide electrical energy for the light system. The electroluminescent lamp includes a substrate, a rear electrode, a dielectric layer, a phosphor layer, a conductive layer, and a front electrode. The lamp further includes a tab interconnect tab portion, which receives the leads from the rear electrode and front electrode, and is configured to be releasably and fixedly mated with the connector.

Other features and advantages of the invention will become apparent from the following description and from the claims.

### BRIEF DESCRIPTION OF THE DRAWINGS

FIG. 1 is a flow chart illustrating a sequence of steps for fabricating the electroluminescent lamp shown in FIG. 2;

FIG. 2 is an exploded pictorial illustration of an electroluminescent lamp fabricated in accordance with the steps shown in FIG. 1;

FIG. 3 is a top view of the connector and an interconnect tab portion of the present invention, and

FIG. 4 is a cross-sectional view of the connector taken along line 4-4 of FIG. 3.

### DETAILED DESCRIPTION OF THE INVENTION

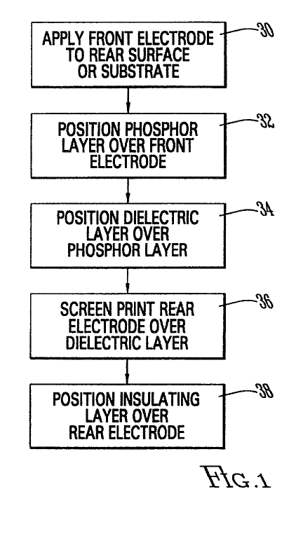

FIG. 1 is a schematic illustration of one embodiment of an electroluminescent (EL) lighting system 100 of the present invention. The EL lighting system 100 comprises an EL lamp 120 and a connector 200 to provide electrical energy for the light system. The EL lamp 120 includes a substrate 122, a rear electrode 128, a dielectric layer 130, a phosphor layer 132, a conductive layer 134, and a front outlining electrode 136. The EL lamp further includes a tab interconnect tab portion 173, which receives the lead from the rear electrode 128 and front outlining electrode 136, and is configured to be releasably and fixedly mated with the connector 200.

More particularly, substrate 122, in one embodiment, is a paper based substrate, such as card board or 80 point card stock, and includes a front surface 124 and a rear surface 126. A rear electrode 128 is formed on front surface 124 of substrate 122. Rear electrode 128 is formed of conductive particles, e.g., silver or carbon, dispersed in a polymeric binder to form a screen printable ink. In one embodiment, rear electrode 128 is heat curable available from Dupont, of Wilmington, Del. In an alternative embodiment, rear electrode 128 is UV curable such as available from Allied PhotoChemical Inc, of Port Huron, Mich.

A dielectric layer 130 is formed over rear electrode 128 from high dielectric constant material, such as barium titanate dispersed in a polymeric binder to form a screen printable ink. In one embodiment, the dielectric screen printable ink is heat curable such as available from Dupont, of Wilmington, Del. In an alternative embodiment, dielectric layer 130 is UV curable available from Allied PhotoChemical Inc, of Port Huron, Mich.

A phosphor layer 132 is formed over dielectric layer 130 and may be formed of electroluminescent phosphor particles, e.g., zinc sulfide doped with copper or manganese that are dispersed in a polymeric binder to form a screen printable ink. In one embodiment, the phosphor screen printable ink is heat curable available from Dupont, of Wilmington, Del. In an alternative embodiment, phosphor layer 132 is UV curable such as available from Allied PhotoChemical Inc, of Port Huron, Mich.

A sealant layer 133 is formed over dielectric layer 130 and is preferably a solvent based in a screen-printable carrier. Sealant layer 133 is then UV cured, for example, for approximately two to five seconds under a UV lamp.

A conductor layer 134 is formed on phosphor layer 132 from indium-tin-oxide particles that form a screen printable ink which is heat curable available from Dupont, of Wilmington, Del. In an alternative embodiment, conductor layer 134 is UV curable available from Allied PhotoChemical Inc, of Port Huron, Mich.

A front outlining electrode 136 is formed on lamp 120 from silver particles that form a screen printable ink which is heat curable available from Dupont, of Wilmington, Del. In an alternative embodiment, front outlining electrode 136 is UV curable available from Allied PhotoChemical Inc, of Port Huron, Mich.

A front outlining insulating layer 138 is formed over front outlining electrode 136 from high dielectric constant material, such as barium titanate dispersed in a polymeric binder to form a screen printable ink. In one embodiment, the front outlining insulator is heat curable available from Dupont, of Wilmington, Del. In an alternative embodiment, front outlining insulator 138 is UV curable available from Allied PhotoChemical Inc, of Port Huron, Mich.

A protective coating 140 formed, for example, from a ultraviolet (UV) coating available from Dupont, of Wilmington, Del. is then formed on lamp 120 over rear electrode 128, dielectric layer 130, phosphor layer 132, sealant layer 133, conductor layer 134, front outlining electrode 136, and front outlining insulating layer 138.

FIG. 1 illustrates a sequence of steps 140 for fabricating EL lamp 120. EL lamp 120 may, for example, have a metal substrate, e.g., 0.25 mm gauge aluminum, a plastic substrate, e.g., 0.15 mm heat stabilized polycarbonate, or a paper based substrate, e.g., 80 pt. card stock. With respect to an EL lamp utilizing a plastic substrate, a rear electrode is formed 142 on a front surface of EL lamp 120. Next, a dielectric layer is formed 144 over the rear electrode and extends beyond an illumination area for the design. Subsequently, a phosphor layer is formed 146 over the dielectric layer and preferably is formed to define the illumination area. A sealant layer is then formed 147 over the remaining exposed portion of the dielectric layer. A layer of indium tin oxide ink is formed 148 over the phosphor layer, a front outlining electrode is then formed 150 on the sealant layer and a front outlining insulating layer is formed 152 on the front outlining electrode layer. A protective coat is then applied 154 over the layers of the EL lamp 120.

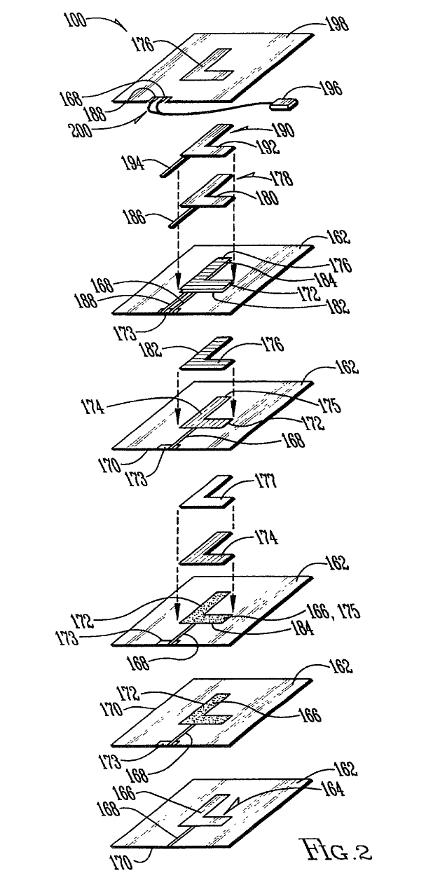

More particularly, and referring now to FIG. 2, an EL sign 160 includes a plastic substrate. The substrate has a front surface 162 and a rear surface (not shown) and is first positioned in an automated flat bed screen printing press (not shown). A rear electrode 164, such as screen printable carbon or silver, having an illumination area 166 and a rear electrode lead 168 is screen printed onto front surface 162 of sign 160. Illumination portion 166 defines a shape, e.g., an “L”, representative of the ultimate image to be illuminated by sign 160, although not extending to the extent of an illumination area hereinafter defined.

Rear electrode lead 168 extends from illumination area 166 to a perimeter 170 of sign front surface 162. Rear electrode 164 is screen printed as a positive, or forward, image, e.g., as “L” rather than as a reverse “L”. After printing rear electrode 164 on front surface 162, rear electrode 164 is cured to dry. For example, rear electrode 164 and sign 160 may be positioned in a reel to reel oven for approximately two minutes at a temperature of about 250-350 degrees Fahrenheit. In an alternative embodiment, rear electrode 164 and sign 160 are cured by exposure to UV light for about two to about five seconds.

A dielectric layer 172 is then screen printed onto lamp surface 162 so that dielectric layer 172 covers substantially the entire illumination portion 166 while leaving rear electrode lead 168 covered entirely except for an interconnect tab portion 173. In one embodiment, interconnect tab portion 173 is about 0.5 inches wide by about 1.0 inch long. Dielectric layer 172 includes two layers (not shown) of high dielectric constant material, such as barium titanate dispersed in a polymeric binder. The first layer of barium titanate is screen printed over rear electrode 164 and cured to dry for approximately two minutes at a temperature of about 250-350 degrees Fahrenheit. In an alternative embodiment, the first layer of barium titanate is cured by exposure to UV light for about two to about five seconds.

The second layer of barium titanate is screen printed over the first layer of barium titanate and cured to dry for approximately two minutes at a temperature of about 250-350 degrees Fahrenheit to form dielectric layer 172. In an alternative embodiment, the second layer of barium titanate is cured by exposure to UV light for about two to about five seconds. In accordance with one embodiment, dielectric layer 172 has substantially the same shape as illumination portion 166, but is approximately 5%-25% larger than illumination portion 166.

In an alternative embodiment, dielectric layer includes a high dielectric constant material such as alumina oxide dispersed in a polymeric binder. The alumina oxide layer is screen printed over rear electrode 164 and cured by exposure to UV light for about two to about five seconds.

After screen printing dielectric layer 172 and rear electrode 164 to lamp surface 162, a phosphor layer 174 is screen printed onto sign surface 162 over dielectric layer 172. Phosphor layer 174 is screened as a forward, or positive, image, e.g., as “L”, rather than a reverse image, e.g., as a reverse image of “L”. Phosphor layer has substantially the same shape as illumination portion 166 and is approximately 5% to 15% larger than illumination portion 166 to define an illumination area 175. Art work utilized to create a screen for phosphor layer 174 is the same art work utilized to create a screen for rear electrode 164, except for rear electrode lead 168. However, two different screens are utilized for phosphor layer 174 and rear electrode 164 since each screen is specific to a different mesh count. Phosphor layer 174 is then cured, for example, for approximately two minutes at about 250-350 degrees Fahrenheit. In an alternative embodiment, phosphor layer 174 is cured by exposure to UV light for about two to about five seconds.

A sealant layer 177 is screen printed onto sign surface 162 over the remaining exposed portions of dielectric layer 172. Sealant layer 177 is then cured, for example, for approximately two minutes at about 250-350 degrees Fahrenheit. In an alternative embodiment, sealant layer 175 is cured by exposure to UV light for about two to about five seconds.

A conductor layer 176 formed from indium-tin-oxide is screen printed over phosphor layer 174. Conductor layer 176 has substantially the same shape and size as illumination area 175 and may, for example, be screen printed with the same screen utilized to print phosphor layer 174. Conductor layer 176 also is printed as a forward image and is cured, for example, for approximately two minutes at about 250-350 degrees Fahrenheit. In an alternative embodiment, conductor layer 176 is cured by exposure to UV light for about two to about five seconds.

In one embodiment, conductor layer is non-metallic and is translucent and transparent, and is synthesized from a conductive polymer, e.g., poly-phenyleneamine-imine. The non-metallic conductor layer is heat cured for approximately two minutes at about 200 degrees Fahrenheit.

Subsequently, a front electrode or bus bar—hereinafter front outlining electrode layer 178—fabricated from silver ink is screen printed onto lamp surface 162 over sealant layer 175 to outline the illumination area 175. Front outlining electrode is configured to transport energy to conductor layer 176. Particularly, front electrode 178 is screen printed to lamp surface 162 so that a first portion 180 of front outlining electrode layer 178 contacts an outer perimeter 182 of conductor layer 176. In addition, first portion 180 contacts an outer perimeter 184 of illumination area 166 and an outer perimeter 186 of a front electrode lead 188 which extends from illumination area 166 to perimeter 170 of sign surface 162. Front outlining electrode layer 178 is then cured for approximately two minutes at about 250-350 degrees Fahrenheit. In an alternative embodiment, front outlining electrode layer 178 is cured by exposure to UV light for about two to about five seconds.

In a preferred embodiment, front outlining electrode layer 178 is configured such that it contacts substantially the entire outer perimeter 182 of conductor layer 176 and overlaps rear electrode 164 only at the rear electrode lead 168. This minimized crossover design having an additional sealant layer 177 that seals any pinholes and channels in the dielectric layer significantly reduces failures of the lamp. In an alternative embodiment, front electrode first portion 180 contacts only about 25% of outer perimeter 182 of conductor layer 176. Of course, front electrode first portion 180 could contact any amount of the outer perimeter of conductor layer 176 from about 25% to about 100%.

In an alternative embodiment, the order of application of conductor layer 176 and front outlining electrode layer 178 is reversed such that front outlining electrode layer 176 is applied immediately after phosphor layer 174 is applied, and conductor layer 176 is applied after front outlining electrode layer 178. A front outlining insulator layer 190 is then applied immediately after conductor layer 176.

A front outlining insulator layer 190 is screen printed onto front outlining electrode layer 178 and covers front outlining electrode 178 and extends beyond both sides of front outlining electrode by about 0.125 inches. Front outlining insulator layer 190 is a high dielectric constant material, such as barium titanate dispersed in a polymeric binder. Front outlining insulator layer 190 is screen printed onto front outlining electrode layer 178 such that front outlining insulator layer 190 covers substantially the entire front outlining electrode layer 178. Front outlining insulator layer 190 is cured for approximately two minutes at about 250-350 degrees Fahrenheit. In an alternative embodiment, front outlining insulator layer 190 is cured by exposure to UV light for about two to about five seconds.

The size of front outlining insulating layer 190 depends on the size of front outlining electrode layer 178. Front outlining electrode layer 190 thus includes a first portion 192 that substantially covers front outlining electrode layer first portion 180 and a second portion 194 that substantially covers front electrode lead 188 which extends from illumination area 166 to perimeter 170 of lamp 162.

Interconnect tab portion 173 of front electrode lead 188 remains uncovered so that a power source 196 can be connected thereto. Rear electrode 164, dielectric layer 172, phosphor layer 174, conductor layer 176, front outlining electrode layer 178, and front outlining insulating layer 190 form EL sign 160 extending from front surface 162 of the substrate.

A decorative background layer 198 utilizing a four-color process is then screen printed on front surface 162 of sign 160. Background layer 198 substantially covers front surface 162 except for illumination area 166 and tab interconnect portion 173. However, in some cases, background layer 198 is printed directly over illumination area 166 to provide a gradated, halftone, grainy illumination quality.

Particularly, background layer 198 is screen printed on front surface 162 so that substantially only background layer 198 and conductor layer 176 are visible from a location facing front surface 162. Background layer 198 may include, for example, conventional UV screen printing ink and may be cured in a UV dryer utilizing known sign screening practices

After applying rear electrode 164, dielectric layer 172, phosphor layer 174, conductor layer 176, front outlining electrode layer 178, front outlining insulating layer 190, and background layer 198 to sign 160, sign 160 may, for example, be hung in a window, on a wall, or suspended from a ceiling. Power supply 196 is then coupled to front electrode lead 188 and rear electrode lead 168 and a voltage is applied across rear electrode 164 and front electrode 178 to activate phosphor layer 174. Particularly, current is transmitted through front electrode 178 to conductor layer 176, and through rear electrode 164 to illumination area 166 to illuminate the letter “L”.

In accordance with one embodiment, rear electrode 164 is approximately 0.6 millimeters thick, dielectric layer 172 is approximately 1.2 millimeters thick, phosphor layer 174 is approximately 1.6 millimeters thick, conductor layer 176 is approximately 1.6 millimeters thick, front electrode 178 is approximately 0.6 millimeters thick, and background layer 184 is approximately 0.6 millimeters thick. Of course, each of the various thicknesses may vary.

Interconnect tab portion 173 is adjacent sign perimeter 170 and remains uncovered to facilitate attachment of a slide connector 200 and wire harness from a power supply 196 to front electrode lead 188 and rear electrode lead 168.

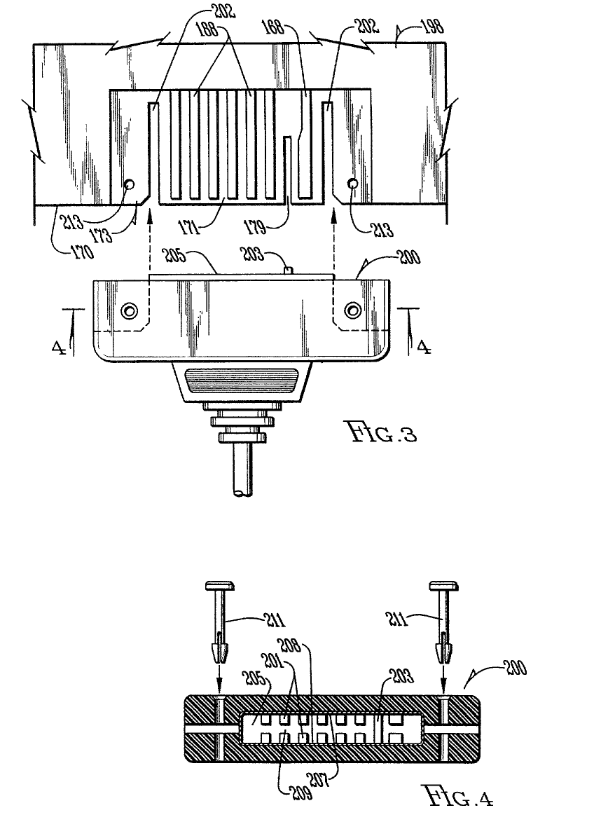

In a preferred embodiment shown in FIG. 3, tab interconnect portion 173 includes two slots 202 die cut into the substrate to define a male end 175. The male end 175 is mateably received by slide connector 200 such that the connector is mounted to tab interconnect portion 173. Tab interconnect portion 173 further includes a key slot 177, which is die cut into the substrate and a pair of locking holes 213 on either side of the front electrode lead and the rear electrode lead.

As shown in FIG. 3, slide connector 200 is configured to entirely surround exposed leads 168 and 188, i.e., the portion of leads 168 and 188 that have been left uncovered. Connector 200 has an opening 205 to receive the male end 175 of interconnect portion 173.

Slide connector 200 includes copper contacts 201 that are spring-mounted to both a top and bottom wall, 207, 208, respectively, of connector 200. The copper contacts are coaligned such that they provide a gap 209 between the contacts of about 0.02 to 0.05 in. It will be appreciated by those skilled in the art that the contacts on the upper and lower walls of the connector opening may define an opening that would be a compression fit with the male end 175 of the tab interconnect portion 173.

Slide connector 200 further includes a pin 203 that ensures that slide connector 200 is properly oriented on tab interconnect portion 173. Preferably, pin 203 is positioned in the connector opening 205 between the rear electrode lead contact and the front electrode lead contact and is offset therein, as shown in FIG. 3. This insures that the slide connector 200 is incapable of being incorrectly attached.

In one embodiment, slide connector 200 is fixedly attached to interconnect tab portion 173 with a push pins 211 or other similar fastener. Push pins 211 are mounted to the connector 200 to be in alignment with locking holes 213 when the connector is properly mated with the interconnect tab portion 173.

The above described EL system can be utilized in a variety of functions. For example, the signs can be used as a display panel for a vending machine, a display panel for an ice machine, an illuminated panel for a helmet, a road sign, a display panel in games of chance, e.g., slot machines, and as point of purchase signage.

The above described embodiments are exemplary and are not meant to be limiting. The above described method provides for an illuminated sign having an EL lamp that is fabricated directly on the sign, i.e., a prefabricated EL lamp is not coupled to the sign. Such method also facilitates applying each layer of the EL lamp to the EL substrate as a positive image, rather than a reverse image. However, the above described embodiment is exemplary, and is not meant to be limiting.

What is claimed is:

1. A sign comprising a surface and an illuminated design coupled thereto, said illuminated design comprising:
a first electrode formed on said sign surface, said first electrode having a lead that extends to a perimeter of the surface of the sign;
a luminescent layer substantially aligned with said first electrode;
a conductor layer substantially aligned with said luminescent layer;
a second electrode formed onto said surface of said sign, said outlining electrode being configured to transport energy to said conductor layer;
an interconnect tab portion having a male end, and a connector for releasably mating with said interconnect tab portion and for providing electrical power to said first electrode and said second electrode.

2. A sign in accordance with claim 1 wherein said connector includes a locking pin for locking said connector to said surface of said sign.

3. A sign in accordance with claim 1 wherein said connector includes a key pin for aligning the connector with the interconnect tab portion.

4. A sign in accordance with claim 3 wherein said connector includes contacts for the first and second electrode.

5. A sign in accordance with claim 4 wherein said connector includes a key positioned between said contacts for the first and second electrode such that said connector is mountable to said interconnect tab portion in a proper alignment.

6. A sign comprising a surface and an illuminated design coupled thereto, said illuminated design comprising:
a first electrode formed on said sign surface, said first electrode defining a first perimeter;
a dielectric layer screen printed onto said first electrode and sign surface, said dielectric layer being substantially aligned with said first electrode and defining a dielectric perimeter, the dielectric perimeter extending beyond the first perimeter of the first electrode,
a phosphor layer formed on said dielectric layer and substantially aligned with said first electrode, the phosphor layer defining a second perimeter, the dielectric layer perimeter extending beyond the second perimeter of said phosphor layer to define an exposed dielectric layer;
a sealing layer formed on at least a portion of said exposed dielectric layer to electrically seal the dielectric layer;
a conductor layer substantially aligned with said phosphor layer and defining a third perimeter;
an outlining electrode formed onto the sealing layer and substantially circumscribing at least one of said second perimeter and third perimeter, said outlining electrode being configured to transport energy to said conductor layer,
an interconnect tab portion having a male end, and
a connector for releasably mating with said interconnect tab portion and for providing electrical power to said first electrode and said outlining electrode.

7. A sign in accordance with claim 6 wherein said connector includes a locking pin for locking said connector to said surface of said sign.

8. A sign in accordance with claim 6 wherein said connector includes a key pin for aligning the connector with the interconnect tab portion.

9. A sign in accordance with claim 6 wherein said connector includes contacts for the first and second electrode.

10. A sign in accordance with claim 9 wherein said connector includes a key positioned between said contacts for the first and second electrode such that said connector is mountable to said interconnect tab portion in a proper alignment.

11. A sign in accordance with claim 6 wherein said first electrode comprises a rear electrode, said rear electrode being screen printed on said substrate as a forward image.

12. A sign in accordance with claim 6 wherein at least one of said first electrode and outlining electrode is comprised of silver particles.

13. A sign in accordance with claim 12 wherein said dielectric layer is comprised of barium-titanate particles, and wherein said sealing layer comprises a barrier to prevent silver migration between said first electrode and said outlining electrode.
